(19) United States
(12) Patent Application Publication
(10) Pub. No.: US 2025/0113739 A1
(43) Pub. Date: Apr. 3, 2025

(54) PIEZOELECTRIC THIN-FILM, PIEZOELECTRIC THIN-FILM MANUFACTURING DEVICE, PIEZOELECTRIC THIN-FILM MANUFACTURING METHOD, AND FATIGUE ESTIMATION SYSTEM

(71) Applicant: TOHOKU UNIVERSITY, Sendai-shi, Miyagi (JP)

(72) Inventors: Hiroki KUWANO, Sendai-shi (JP); Tadashi KATO, Sendai-shi (JP); Van Minh LE, Sendai-shi (JP); Hoang Hung NGUYEN, Sendai-shi (JP); Riyo KONNO, Sendai-shi (JP); Yosuke TAKAMAYA, Sendai-shi (JP)

(73) Assignee: TOHOKU UNIVERSITY, Sendai-shi, Miyagi (JP)

(21) Appl. No.: 18/724,863

(22) PCT Filed: Dec. 28, 2021
(86) PCT No.: PCT/JP2021/048836

§ 371 Date: Dec. 5, 2024

(51) Int. Cl. H10N 30/00; G01L 1/16; H10N 30/093; H10N 30/85

(52) U.S. Cl. CPC H10N 30/704; G01L 1/16; H10N 30/093; H10N 30/85

(57) ABSTRACT

A piezoelectric thin film having better FoM and piezoelectric strain constant, a manufacturing apparatus and manufacturing method, and a fatigue estimation system using the film; wherein, the piezoelectric thin film is made of (MgHf)ₓAl₁₋ₓN in which Mg and Hf are co-doped into the Al site of AlN, where x is 0.3 or more and 0.49 or less, and has a figure of merit (FoM) of 45 GPa or more and a piezoelectric strain constant (d₃₃) of 18 pm/V or more. Multiple first pieces made of Mg and multiple second pieces made of Hf are on the surface of a target made of AlN wherein an average surface area of each first piece is 0.9 to 1.1 times an average surface area of each second piece with respect to a surface area of the target, and a piezoelectric thin film is grown on a substrate by magnetron sputtering.

### FIELD OF THE INVENTION

The present invention relates to a piezoelectric thin film, a piezoelectric thin film manufacturing apparatus, a piezoelectric thin film manufacturing method, and a fatigue estimation system.

### DESCRIPTION OF RELATED ART

Conventionally, lead zirconate titanate (PZT) has been widely used as a piezoelectric material used in sensors, actuators, and the like, but since it contains a large amount of lead (Pb), which is a toxic substance, the development of a piezoelectric material to replace PZT has been progressing in recent years. AlN (aluminum nitride) is known as one of the piezoelectric materials to replace PZT, but in order to further increase the figure of merit (FoM=e₃₁²/ε·ε_{γ}; where e₃₁ is the piezoelectric stress constant, ε is the dielectric constant, and ε_{γ} is the relative dielectric constant), a material in which Mg and Hf are co-doped at the Al site has been developed (see, for example, NPTLs 1 to 4).

In particular, the present inventors have confirmed that in a (MgHf)ₓAl₁₋ₓN thin film in which Mg and Hf are co-doped at the Al site, the FoM increases as x increases, and when x=0.12, an FoM three times that of AlN is obtained (see, for example, NPTL 5). The present inventors have also developed a piezoelectric thin film with an even larger value of x, and have confirmed that an even better FoM is obtained when x is 0.15 or more and 0.5 or less (see, for example, PTL 1).

### CITATION LIST

### Patent Literature

Patent Literature 1: JP-A-2019-169612

### Non-Patent Literature

Non-Patent Literature 1: Nguyen H H, Oguchi H, Minh L V, and Kuwano H, “High-Throughput Investigation of a Lead-Free AlN-Based Piezoelectric Material, (Mg,Hf)ₓAl₁₋ₓN”, ACS Comb. Sci., 2017, 19, p. 365-369
Non-Patent Literature 2: Nguyen H H, Oguchi H, and Kuwano H, “Combinatorial approach to MgHf co-doped AlN thin films for Vibrational Energy Harvesters”, J. Phys.: Conf. Ser., 2016, 773 012075
Non-Patent Literature 3: Y. Iwazaki, T. Yokoyama, T. Nishihara, and M. Ueda, “Highly enhanced piezoelectric property of co-doped AlN”, Appl. Phys. Express, 2015, 8, 061501
Non-Patent Literature 4: Yoichiro Ogata, Tsuyoshi Yokoyama, Yoshinori Iwasaki, Tokihiro Nishihara, “Crystallographic site analysis of Mg in Mg/Hf co-doped AlN thin film”, Ritsumeikan University, Research Organization of Science and Technology, [Retrieved Mar. 8, 2018], Internet <URL: http://www.ritsumei.ac.jp/acd/re/src/report/platform/R1515.pdf>
Non-Patent Literature 5: H. H. Nguyen, L. Van Minh, H. Oguchi, and H. Kuwano, “High figure of merit” (MgHf)ₓAl₁₋ₓN thin films for miniaturizing vibrational energy harvesters”, Proceedings of PowerMEMS 2017, 2017, W3A.1

### SUMMARY OF THE INVENTION

### Problems Invention Seeks to Solve

The piezoelectric thin film described in PTL 1 is manufactured by growing on a substrate by reactive ion beam sputtering using two targets, an MgHf target and an AlN target, and two sputter guns corresponding to each target. When x=0.44, a maximum FoM of 31.5 GPa and a maximum piezoelectric strain constant (d₃₃) of 13.68 pm/V are obtained, but there is a constant demand for the development of piezoelectric thin films with a better FoM and piezoelectric strain constant.

The present invention has been made with a focus on such problems, and an object thereof is to provide a piezoelectric thin film with a better FoM and piezoelectric strain constant, a piezoelectric thin film manufacturing apparatus and a piezoelectric thin film manufacturing method capable of manufacturing such a piezoelectric thin film, and a fatigue estimation system capable of using such a piezoelectric thin film.

### Means to Solve Problems

To achieve the above object, a piezoelectric thin film according to the present invention is a piezoelectric thin film made of a thin film of (MgHf)ₓAl₁₋ₓN in which Mg and Hf are co-doped into the Al site of AlN, where x is 0.3 or more and 0.49 or less, a figure of merit (FoM) is 45 GPa or more, and a piezoelectric strain constant (d₃₃) is 18 pm/V or more.

A piezoelectric thin film manufacturing apparatus according to the present invention is a piezoelectric thin film manufacturing apparatus for manufacturing a piezoelectric thin film in which Mg and Hf are co-doped into the Al site of AlN using magnetron sputtering, the apparatus including: a target made of AlN; a plurality of first pieces made of Mg arranged on a surface of the target; and a plurality of second pieces made of Hf arranged on the surface of the target, wherein an average surface area of each of the plurality of first pieces is 0.9 to 1.1 times an average surface area of each of the plurality of second pieces with respect to a surface area of the target.

A piezoelectric thin film manufacturing method according to the present invention is a piezoelectric thin film manufacturing method, including: arranging a plurality of first pieces made of Mg and a plurality of second pieces made of Hf on a surface of a target made of AlN such that an average surface area of each of the plurality of first pieces is 0.9 to 1.1 times an average surface area of each of the plurality of second pieces with respect to a surface area of the target; and growing a piezoelectric thin film in which Mg and Hf are co-doped at the Al site of AlN on a substrate by magnetron sputtering.

The piezoelectric thin film according to the present invention can be suitably manufactured by the piezoelectric thin film manufacturing apparatus according to the present invention and/or the piezoelectric thin film manufacturing method according to the present invention. The piezoelectric thin film manufacturing apparatus according to the present invention can also suitably carry out the piezoelectric thin film manufacturing method according to the present invention. In the piezoelectric thin film manufacturing apparatus and the piezoelectric thin film manufacturing method according to the present invention, since one sputtering gun is used to sputter the surface of an AlN target on which a plurality of first pieces made of Mg and a plurality of second pieces made of Hf are arranged, a piezoelectric thin film of (MgHf)ₓAl₁₋ₓN can be obtained with higher accuracy than a conventional method using two targets and two sputtering guns.

In addition, in the piezoelectric thin film manufacturing apparatus and the piezoelectric thin film manufacturing method according to the present invention, it is possible to easily control the addition ratio of Mg and Hf by controlling the ratio of the average surface area of each of the first pieces to the average surface area of each of the second pieces with respect to the surface area of the target. In particular, by controlling the average surface area of each of the first pieces to be 0.9 to 1.1 times the average surface area of each of the second pieces, a piezoelectric thin film of (MgHf)ₓAl₁₋ₓN having an excellent FoM and piezoelectric strain constant can be obtained. In addition, by growing the piezoelectric thin film using the piezoelectric thin film manufacturing method according to the embodiment of the present invention so that the ratio of the total number of Mg and Hf atoms to the number of Al atoms is 30:70 to 49:51, a piezoelectric thin film according to the present invention having a better FoM and piezoelectric strain constant can be obtained.

In the piezoelectric thin film manufacturing method according to the present invention, it is particularly preferable to grow the piezoelectric thin film so that the ratio of the total number of Mg and Hf atoms to the number of Al atoms is 45:55 to 49:51. In this case, a piezoelectric thin film can be obtained in which x is 0.45 or more and 0.49 or less, the figure of merit (FoM) is 65 GPa or more, and the piezoelectric strain constant (d₃₃) is 23 pm/V or more.

A fatigue estimation system according to the present invention is a fatigue estimation system for estimating cumulative fatigue of a measurement object, including: a sensor unit having a piezoelectric body, the sensor unit being provided so that a force is applied to the piezoelectric body due to strain caused by fatigue in the measurement object, and an electric charge is generated in the piezoelectric body; a charge storage means for storing the electric charge generated in the piezoelectric body of the sensor unit; a transmission means for wirelessly transmitting charge information related to the amount of electric charge each time a predetermined amount of electric charge is stored in the charge storage means; and a fatigue estimation means for recording a reception time each time the charge information is received from the transmission means and estimating the cumulative fatigue of the measurement object based on the number of times the reception time is recorded.

In the fatigue estimation system according to the present invention, since the strain caused in the measurement object due to fatigue can be detected using the piezoelectric body, the power required for detection can be reduced. In addition, since the charge information is transmitted only when a predetermined amount of electric charge is stored in the charge storage means, the power required for transmission can be reduced. In the fatigue estimation system according to the present invention, the cumulative amount of strain caused in the measurement object can be grasped based on the number of reception times at which the charge information is received, and the cumulative fatigue of the measurement object can be easily estimated. In addition, the accumulation status of fatigue over time can be grasped from the reception time of the charge information.

The fatigue estimation system according to the present invention may use the charge stored in the charge storage means as power for operating the transmission means and the like in order to further reduce the power consumption on the measurement object. In addition, the charge information may be any information, such as information indicating the amount of charge, as long as it is information that indicates that a predetermined amount of charge has been stored.

In the fatigue estimation system according to the present invention, the measurement object is preferably a structure or a member. In this case, the cumulative fatigue of the structure or member can be estimated, and the destruction of the structure or member due to fatigue accumulation can be prevented. In the fatigue estimation system according to the present invention, the piezoelectric body is preferably made of the piezoelectric thin film according to the present invention. In this case, the cumulative fatigue can be estimated with high accuracy.

### Effect of Invention

According to the present invention, it is possible to provide a piezoelectric thin film with a better FoM and piezoelectric strain constant, a piezoelectric thin film manufacturing apparatus and a piezoelectric thin film manufacturing method capable of manufacturing such a piezoelectric thin film, and a fatigue estimation system capable of using such a piezoelectric thin film.

### BRIEF DESCRIPTION OF THE DRAWINGS

FIG. 1 is a side view showing an apparatus for determining the piezoelectric strain constant d₃₃ of a piezoelectric thin film according to an embodiment of the present invention.

FIG. 2 is a graph showing the relationship between the total concentration of MgHf and the piezoelectric strain constant d₃₃ of a piezoelectric thin film according to an embodiment of the present invention.

FIG. 3 is a graph showing (a) the relationship between an applied voltage and a displacement, and (b) the relationship between an applied voltage and a piezoelectric strain constant d₃₁, when x=0.2, of a cantilever-shaped measurement sample having a (MgHf)ₓAl₁₋ₓN thin film, which is a piezoelectric thin film according to an embodiment of the present invention.

FIG. 4 is a graph showing the relationship between the frequency of the applied voltage and the capacitance when x=0.2, of a cantilever-shaped measurement sample having a (MgHf)ₓAl₁₋ₓN thin film, which is a piezoelectric thin film according to an embodiment of the present invention.

FIG. 5 is a graph showing the relationship between the total concentration of MgHf and the figure of merit (FoM) of a piezoelectric thin film according to an embodiment of the present invention.

FIG. 6 is a block diagram showing the configuration of a fatigue estimation system according to an embodiment of the present invention.

### DETAILED DESCRIPTION OF THE INVENTION

Hereinafter, an embodiment of the present invention will be described based on examples.

A piezoelectric thin film according to an embodiment of the present invention is made of a thin film of (MgHf)ₓAl₁₋ₓN in which Mg and Hf are co-doped at the Al site of AlN, and x is 0.3 or more and 0.49 or less.

The piezoelectric thin film according to an embodiment of the present invention can be manufactured by a piezoelectric thin film manufacturing apparatus and a piezoelectric thin film manufacturing method according to an embodiment of the present invention. That is, the piezoelectric thin film manufacturing apparatus according to the embodiment of the present invention has a target made of AlN, a plurality of first pieces made of Mg arranged on the surface of the target, and a plurality of second pieces made of Hf arranged on the surface of the target. Each of the first pieces and each of the second pieces are arranged so that the average surface area of each of the first pieces is 0.9 to 1.1 times the average surface area of each of the second pieces with respect to the surface area of the target.

In the piezoelectric thin film manufacturing method according to the embodiment of the present invention, the surface of the target on which the first pieces and the second pieces are arranged is sputtered by causing ionized Ar gas from a sputter gun to collide with the surface by magnetron sputtering, and a piezoelectric thin film in which Mg and Hf are co-doped at the Al site of AlN is grown on the substrate. In this way, the piezoelectric thin film according to the embodiment of the present invention, which is made of a thin film of (MgHf)ₓAl₁₋ₓN, can be obtained.

In this way, in the piezoelectric thin film manufacturing apparatus and the piezoelectric thin film manufacturing method according to the embodiment of the present invention, since one sputtering gun is used to sputter the surface of an AlN target on which a plurality of first pieces made of Mg and a plurality of second pieces made of Hf are arranged, a piezoelectric thin film of (MgHf)ₓAl₁₋ₓN can be obtained with higher accuracy than a conventional method using two targets and two sputtering guns.

In addition, in the piezoelectric thin film manufacturing apparatus and the piezoelectric thin film manufacturing method according to the embodiment of the present invention, it is possible to easily control the addition ratio of Mg and Hf by controlling the ratio of the average surface area of each of the first pieces to the average surface area of each of the second pieces with respect to the surface area of the target. In particular, by controlling the average surface area of each of the first pieces to be 0.9 to 1.1 times the average surface area of each of the second pieces, a piezoelectric thin film of (MgHf)ₓAl₁₋ₓN having an excellent FoM and piezoelectric strain constant can be obtained. In addition, by growing the piezoelectric thin film using the piezoelectric thin film manufacturing method according to the embodiment of the present invention so that the ratio of the total number of Mg and Hf atoms to the number of Al atoms is 30:70 to 49:51, a piezoelectric thin film according to the present invention having a better FoM and piezoelectric strain constant can be obtained.

### Example 1

The piezoelectric thin film according to the embodiment of the present invention was manufactured using the piezoelectric thin film manufacturing apparatus and the piezoelectric thin film manufacturing method according to the embodiment of the present invention. The magnetron sputtering was performed in an atmosphere of 20% Ar and 80% N₂, and a thin film was grown on the Pt side surface of a substrate made of Pt (100 nm), Ti (6 nm), and SOI. Moreover, the first pieces and the second pieces were arranged so that the average surface area of each of the first pieces was approximately equal to the average surface area of each of the second pieces with respect to the surface area of the target.

In the sputtering, ionized Ar gas from the sputtering gun was collided with the target. At this time, the pressure of each gas was set to 1.5 mTorr, and the temperature of the substrate was set to 600° C. In addition, the base pressure of the sputtering chamber was set to less than 1×10⁻⁷ Torr, and 140 W of high-frequency power was applied to the target. In addition, electrons (e⁻) were supplied from a high-frequency ion source (RF-Neutralizer) to the gas discharged from the sputtering gun.

In the sputtering, the deposition rate of the (MgHf)ₓAl₁₋ₓN thin film was set to 300 nm/h, and the thin film was grown so that the value of x increased from one side of the substrate to the other side. The (MgHf)ₓAl₁₋ₓN thin film thus formed had a thickness of about 700 nm, and the value of x was 0 to 0.45. The value of x in the (MgHf)ₓAl₁₋ₓN thin film can be determined by X-ray photoelectron spectroscopy (XPS) or secondary ion mass spectrometry (SIMS). In addition, unavoidable impurities may be mixed during the manufacturing process.

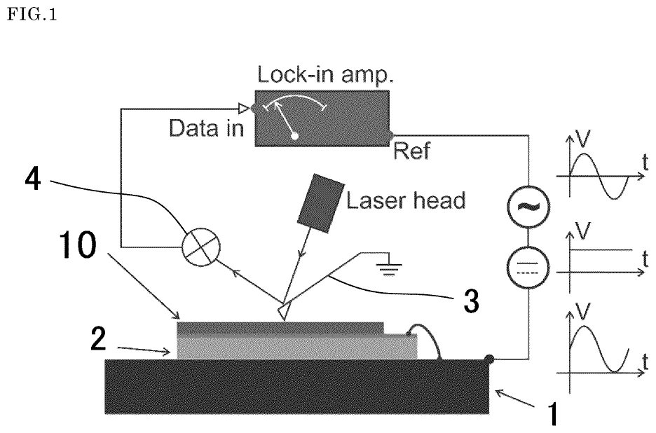

The d₃₃ (piezoelectric strain constant) was determined for various values of x for the manufactured (MgHf)ₓAl₁₋ₓN thin film using the apparatus shown in FIG. 1. As shown in FIG. 1, in the measurement, a substrate 2 was placed on a sample holder 1 with a piezoelectric thin film 10 made of the (MgHf)ₓAl₁₋ₓN thin film facing upward, and a tip of a cantilever 3 was placed close to the surface of the piezoelectric thin film 10. In this state, a sinusoidal voltage was applied between the piezoelectric thin film 10 and the cantilever 3, and the displacement between the surface of the piezoelectric thin film 10 and the tip of the cantilever 3 was measured using a laser Doppler vibrometer (LV-1710 manufactured by Ono Sokki Co., Ltd.) 4. The cantilever 3 used had a Pt-coated surface. The applied voltage was set to 0 to ±20 Vₚₚ, and the frequency was set to 1 to 10 kHz.

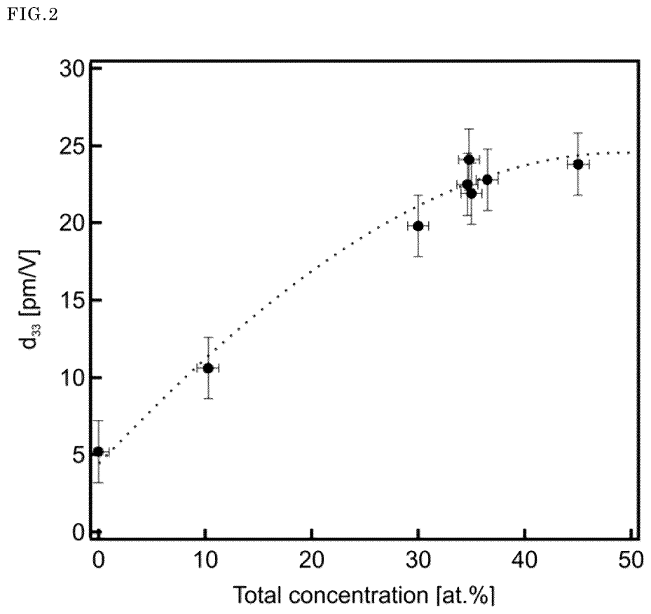

The values of d₃₃ for various values of x are shown in FIG. 2. The horizontal axis of FIG. 2 is the total concentration of MgHf, where the value of x is expressed in atomic percentage (at. %). As shown in FIG. 2, it was confirmed that the value of d₃₃ increases with increasing x, and is about 18 pm/V or more when x=0.3 (30 at. %), about 23 pm/V or more when x=0.45 (45 at. %), and the value is saturated around x=0.5.

### Example 2

Next, the relative dielectric constant (ε_{γ}) and piezoelectric strain constant d₃₁ of the (MgHf)ₓAl₁₋ₓN thin film were measured at various values of x to obtain the figure of merit (FoM). First, in the same manner as in Example 1, a (MgHf)ₓAl₁₋ₓN thin film was formed on a cantilever-shaped substrate. The Pt/Ti of the substrate was used as the lower electrode, and an Au/Cr layer serving as the upper electrode was formed on the surface of the (MgHf)ₓAl₁₋ₓN thin film. In this way, (MgHf)ₓAl₁₋ₓN thin films with various values of x were formed to manufacture measurement samples. The cantilever part of the measurement sample had a width of 1000 μm, the (MgHf)ₓAl₁₋ₓN thin film had a thickness of 5 μm, and the substrate had a thickness of 50 μm. In addition, to avoid geometric errors, measurement samples having cantilever beams with three different lengths, 2000 μm (Device S), 3000 μm (Device M), and 4000 μm (Device L), were manufactured.

For various values of x, the cantilevers of three types of measurement samples were vibrated to determine their respective resonant frequencies, and the Young's moduli were calculated from the amount of deviation of each resonant frequency, and the average value was calculated. A vibration control device (G-Master APD-200 FCG manufactured by Asahi Manufacturing Co., Ltd.) was used to vibrate the cantilever, and a laser Doppler vibrometer (LV-1710 manufactured by Ono Sokki Co., Ltd.) was used to measure the vibration of the cantilever. As a result, for example, when x=0.45 for the (MgHf)ₓAl₁₋ₓN thin film, the resonant frequencies of the measurement samples of Devices S, M, and L were 13884 Hz, 6148 Hz, and 3487 Hz, respectively, and the Young's moduli were 253 GPa, 245 GPa, and 249 GPa, respectively. The average value of the Young's moduli was 249±10 GPa.

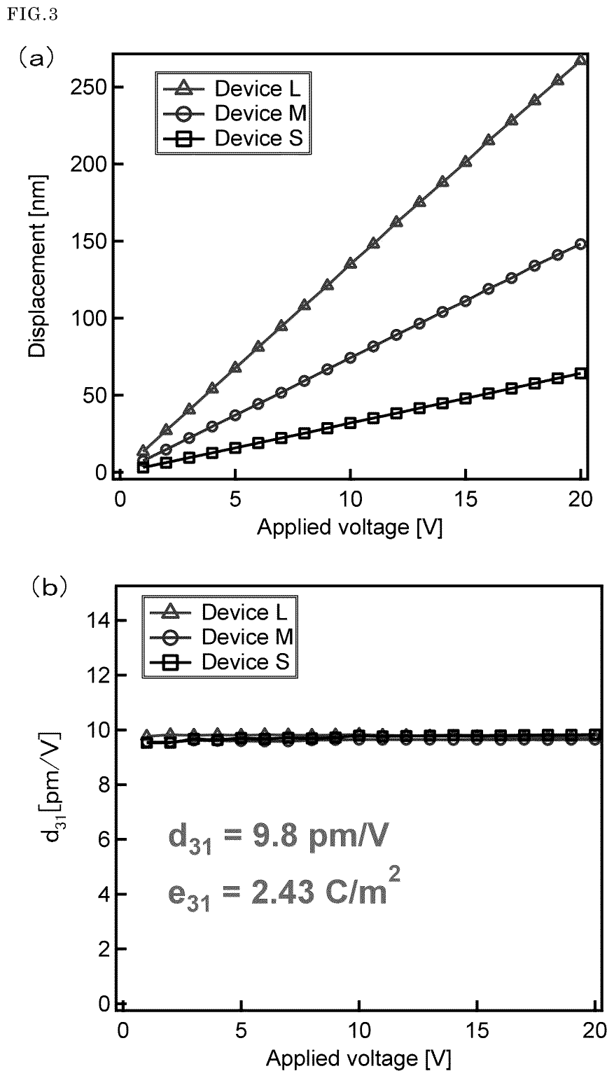

Next, a static voltage of 0 to ±20 Vₚₚ was applied between the lower and upper electrodes of each measurement sample, and the displacement of the tip of the cantilever was measured. FIG. 3(a) shows the relationship between the applied voltage and the displacement obtained for the measurement samples of Devices S, M, and L when x=0.2. FIG. 3(b) shows the relationship between the applied voltage and the piezoelectric strain constant d₃₁ calculated from the displacement in FIG. 3(a). As shown in FIG. 3(b), it was confirmed that the value of d₃₁ was constant at approximately 9.8 pm/V regardless of the applied voltage. The piezoelectric stress constant e₃₁ was calculated as the product of d₃₁ and Young's modulus, and was approximately 2.43 C/m².

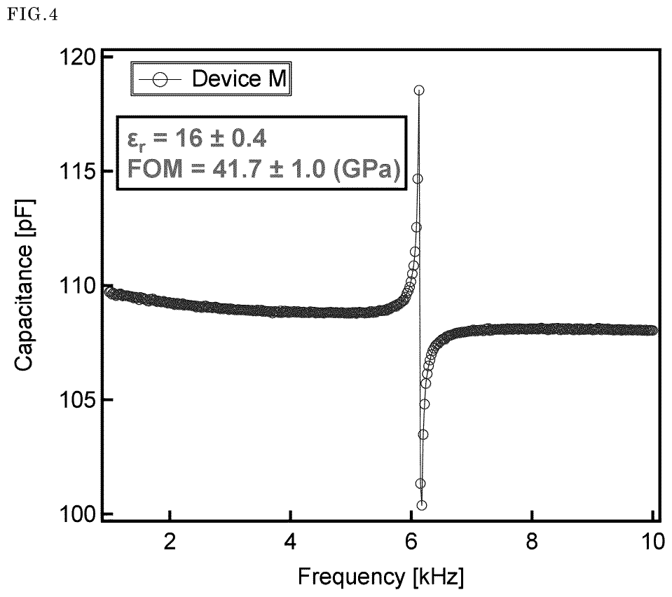

Next, a voltage of 0 to ±20 Vₚₚ at 10 kHz was applied between the lower and upper electrodes of each measurement sample, and the capacitance of the (MgHf)ₓAl₁₋ₓN thin film was measured to determine the relative dielectric constant (ε_{γ}). FIG. 4 shows the relationship between the frequency and capacitance obtained for the measurement sample of Device M when x=0.2. The relative dielectric constant (ε_{γ}) was calculated as 16±0.4 from the results in FIG. 4. From this relative dielectric constant (ε_{γ}) and the piezoelectric stress constant e₃₁ calculated in FIG. 3, the FoM at this time was calculated as 41.7±1.0 GPa.

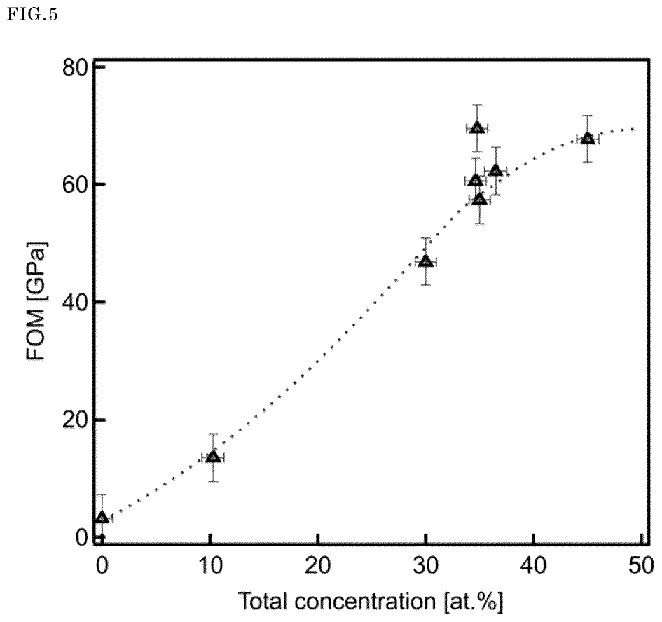

The relationship between various values of x and FoM calculated in a similar manner is shown in FIG. 5. The horizontal axis of FIG. 5 is the total concentration of MgHf, where the value of x is expressed in atomic percentage (at. %). As shown in FIG. 5, it was confirmed that the value of FoM increases with increasing x, and is about 45 GPa or more when x=0.3 (30 at. %), about 65 GPa or more when x=0.45 (45 at. %), and the value is saturated around x=0.5.

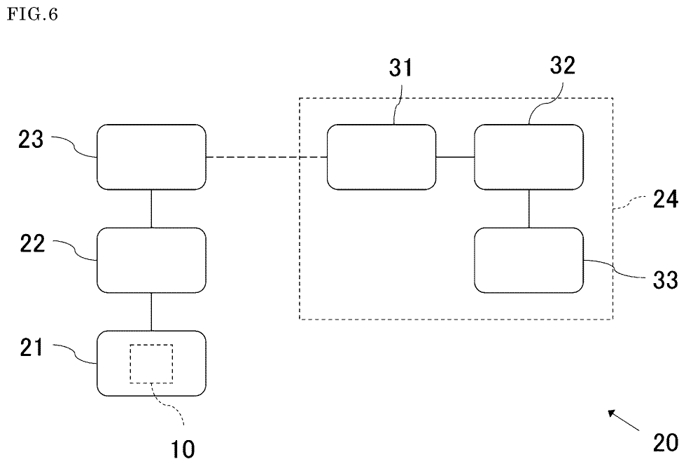

As shown in FIG. 6, a fatigue estimation system according to an embodiment of the present invention is configured using the piezoelectric thin film according to the embodiment of the present invention. As shown in FIG. 6, a fatigue estimation system 20 according to an embodiment of the present invention has a sensor unit 21, a charge storage means 22, a transmission means 23, and a fatigue estimation means 24.

The sensor unit 21 has a (MgHf)ₓAl₁₋ₓN thin film, which is the piezoelectric thin film 10 according to an embodiment of the present invention, and is attached to a measurement object made of a structure or a member. The sensor unit 21 is provided so that a force is applied to the piezoelectric thin film 10 due to strain caused in the measurement object due to fatigue, and an electric charge is generated in the piezoelectric thin film 10.

The charge storage means 22 is made of a charge accumulating element and is connected to the sensor unit 21, and is configured to store the charge generated in the piezoelectric thin film 10 of the sensor unit 21. The transmission means 23 is connected to the charge storage means and is configured to wirelessly transmit charge information related to the charge amount each time a predetermined amount of charge is stored in the charge storage means 22. In a specific example shown in FIG. 6, the charge information is a value of the charge amount.

The fatigue estimation means 24 is configured with a computer and has a receiving means 31, an analysis control unit 32, and a storage means 33. The receiving means 31 is configured to be able to wirelessly receive the charge information transmitted from the transmission means 23. The analysis control unit 32 is connected to the receiving means 31 and the storage means 33. The analysis control unit 32 is configured to send the charge information and the reception time thereof as a timestamp to the storage means 33 each time the receiving means 31 receives the charge information. The analysis control unit 32 is also configured to be able to estimate the cumulative fatigue of the measurement object based on the number of times of the reception time. The analysis control unit 32 is also configured to be able to grasp the accumulation status of fatigue over time from the reception time. The storage means 33 is configured with a memory and is configured to store the charge information and the reception time sent from the analysis control unit 32.

In a specific example shown in FIG. 6, the fatigue estimation means 24 is configured to be able to estimate the cumulative fatigue (damage) of the measurement object made of a structure or member, assuming that the cumulative fatigue (damage) follows the Miner's rule. That is, in the Miner's rule, the damage D is expressed as D=Σ(nᵢ/Nᵢ). Here, nᵢ is the number of repeated stress loads in a certain stress range Δσᵢ, and Nᵢ is the number of repeated breaks (fatigue life) for Δσᵢ. Since the energy of the strain caused in a measurement object due to fatigue is proportional to the power generation output from the piezoelectric thin film 10, by setting the predetermined charge amount when transmitting the charge information from the transmission means 23 to the power generation amount corresponding to Δσᵢ, the number of reception times at the receiving means 31 becomes nᵢ, and the damage D can be estimated.

Next, the effects will be described.

In the fatigue estimation system 20, since the strain caused by fatigue in the measurement object can be detected using the piezoelectric thin film 10, the power required for detection can be reduced. In addition, since the charge information is transmitted only when a predetermined amount of charge is stored in the charge storage means 22, the power required for transmission can be reduced. In the fatigue estimation system 20, the cumulative amount of strain caused in the measurement object can be grasped based on the number of reception times at which the charge information is received, and the cumulative fatigue of the measurement object can be easily estimated. In this way, it is also possible to prevent structures and members from breaking due to fatigue accumulation.

Note that the fatigue estimation system 20 may use the charge stored in the charge storage means 22 as power for operating the transmission means 23 and the like in order to further reduce the power consumption on the measurement object. In addition, although the piezoelectric thin film 10 according to the embodiment of the present invention is used for the sensor unit 21, other piezoelectric bodies can also be used.

### REFERENCE SIGNS LIST

1 Sample holder
2 Substrate
3 Cantilever
4 Laser Doppler vibrometer
10 Piezoelectric thin film
20 Fatigue estimation system
21 Sensor unit
22 Charge storage means
23 Transmission means
24 Fatigue estimation means
31 Reception means
32 Analysis control unit
33 Storage means

1. A piezoelectric thin film made of a thin film of (MgHf)ₓAl₁₋ₓN in which Mg and Hf are co-doped into the Al site of AlN, where x is 0.3 or more and 0.49 or less, a figure of merit (FoM) is 45 GPa or more, and a piezoelectric strain constant (d₃₃) is 18 pm/V or more.

2. The piezoelectric thin film according to claim 1, wherein x is 0.45 or more and 0.49 or less, the figure of merit (FoM) is 65 GPa or more, and the piezoelectric strain constant (d₃₃) is 23 pm/V or more.

3. A piezoelectric thin film manufacturing apparatus for manufacturing a piezoelectric thin film in which Mg and Hf are co-doped into the Al site of AlN using magnetron sputtering, the apparatus comprising:
a target made of AlN;
a plurality of first pieces made of Mg arranged on a surface of the target; and
a plurality of second pieces made of Hf arranged on the surface of the target, wherein
an average surface area of each of the plurality of first pieces is 0.9 to 1.1 times an average surface area of each of the plurality of second pieces with respect to a surface area of the target.

4. A piezoelectric thin film manufacturing method, comprising:
arranging a plurality of first pieces made of Mg and a plurality of second pieces made of Hf on a surface of a target made of AlN such that an average surface area of each of the plurality of first pieces is 0.9 to 1.1 times an average surface area of each of the plurality of second pieces with respect to a surface area of the target; and
growing a piezoelectric thin film in which Mg and Hf are co-doped at the Al site of AlN on a substrate by magnetron sputtering.

5. The piezoelectric thin film manufacturing method according to claim 4, wherein the piezoelectric thin film is grown such that a ratio of a total number of Mg and Hf atoms to the number of Al atoms is 30:70 to 49:51.

6. A fatigue estimation system for estimating cumulative fatigue of a measurement object, comprising:
a sensor unit having a piezoelectric body, the sensor unit being provided so that a force is applied to the piezoelectric body due to strain caused by fatigue in the measurement object, and an electric charge is generated in the piezoelectric body;
a charge storage means for storing the electric charge generated in the piezoelectric body of the sensor unit;
a transmission means for wirelessly transmitting charge information related to the amount of electric charge each time a predetermined amount of electric charge is stored in the charge storage means; and
a fatigue estimation means for recording a reception time each time the charge information is received from the transmission means and estimating the cumulative fatigue of the measurement object based on the number of times the reception time is recorded.

7. The fatigue estimation system according to claim 6, wherein the measurement object is a structure or a member.

8. The fatigue estimation system according to claim 6, wherein the piezoelectric body is made of the piezoelectric thin film of (MgHf)ₓAl₁₋ₓN in which Mg and Hf are co-doped into the Al site of AlN, where x is 0.3 or more and 0.49 or less, a figure of merit (FoM) is 45 GPa or more, and a piezoelectric strain constant (d₃₃) is 18 pm/V or more.

9. The fatigue estimation system according to claim 7, wherein the piezoelectric body is made of the piezoelectric thin film of (MgHf)ₓAl₁₋ₓN in which Mg and Hf are co-doped into the Al site of AlN, where x is 0.3 or more and 0.49 or less, a figure of merit (FoM) is 45 GPa or more, and a piezoelectric strain constant (d₃₃) is 18 pm/V or more.

10. The fatigue estimation system according to claim 6, wherein the piezoelectric body is made of the piezoelectric thin film of (MgHf)ₓAl₁₋ₓN in which Mg and Hf are co-doped into the Al site of AlN, where x is 0.3 or more and 0.49 or less, a figure of merit (FoM) is 45 GPa or more, and a piezoelectric strain constant (d₃₃) is 18 pm/V or more,
wherein x is 0.45 or more and 0.49 or less, the figure of merit (FoM) is 65 GPa or more, and the piezoelectric strain constant (d₃₃) is 23 pm/V or more.

11. The fatigue estimation system according to claim 7, wherein the piezoelectric body is made of the piezoelectric thin film of (MgHf)ₓAl₁₋ₓN in which Mg and Hf are co-doped into the Al site of AlN, where x is 0.3 or more and 0.49 or less, a figure of merit (FoM) is 45 GPa or more, and a piezoelectric strain constant (d₃₃) is 18 pm/V or more,
wherein x is 0.45 or more and 0.49 or less, the figure of merit (FoM) is 65 GPa or more, and the piezoelectric strain constant (d₃₃) is 23 pm/V or more.
